(19) United States
(12) Patent Application Publication
(10) Pub. No.: US 2006/0029734 A1
(43) Pub. Date: Feb. 9, 2006

(54) Film forming method

(75) Inventors: Hideaki Machida, Yamanashi (JP); Takeshi Kada, Yamanashi (JP); Masato Ishikawa, Yamanashi (JP); Naoto Noda, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tri Chemical Laboratories Inc., Kitatsuru-Gun (JP)

(21) Appl. No.: 11/117,399

(22) Filed: Apr. 29, 2005

(30) Foreign Application Priority Data
Aug. 5, 2004 (JP) 2004-229019

(51) Int. Cl. C23C 16/00

(52) U.S. Cl. 427/248.1; 427/226

(57) ABSTRACT

A high-quality insulating film is provided, of which a dielectric constant is lower than that of the conventional SiO₂, and in which no leak current exceeding 10⁻⁸ A/cm² occurs at the time of a voltage of 20 V. A material for forming a film with a chemical vapor deposition process contains one or more chemical compounds selected from the group belonging to the following [I], and one or more chemical compounds selected from the group belonging to the following [II]:
HSi(OCH₃)₃, H₂Si(OCH₃)₂, and HSi(CH₃) (OCH₃)₂ [I]
(CH₂═CH)Si(OCH₃)₃, (CH₂═CH)Si(OC₂H₅)₃, (CH₂═CH)Si(CH₃)(OCH₃)₂, (CH₂═CH)Si(CH₃)(OC₂H₅)₂, (CH₂=CH)Si(CH₃)₂(OCH₃), and (CH₂=CH)Si(CH₃)₂(OC₂H₅) [II]

### BACKGROUND OF THE INVENTION

The present invention relates to insulating films, for example, in semiconductor elements.

At the present moment, the progress in the semiconductor field is remarkable, and LSIs are being converted into ULSIs. And, so as to improve a signal processing speed, forming a fine-grained structure is being developed. This formation of a fine-grained structure has caused wiring conductor materials of which an electric resistance is low to be selected. That is, a transition from tungsten conductor wiring to aluminum conductor wiring, further to copper conductor wiring is now being considered.

By the way, it has been grasped that even though copper, which typifies metal having a low electric resistance, is employed, copper does not give full scope to its characteristic so long as an insulator encircling a copper conductor wiring film is made of SiO₂ which has been conventionally used. In particular, when a wiring conductor width becomes 0.15 μm or less, electromagnetic induction is brought forth on a surrounding insulator at the moment that electrons are caused to flow at a high speed. This adverse effect is conspicuous in a case where the insulator encircling the wiring conductor film is made of an insulating material such as SiO₂ of which a dielectric constant is 4 or more. And, as a result, a delay of signals occurs in some cases, and a crosstalk phenomenon comes out in some cases.

Thereupon, it has been started to make a proposal for selecting the insulating film of which the dielectric constant is lower than that of the conventional SiO₂.

For example, an applicant of this application already proposed an oxide film configured of Si, O, C, and H (JP-P2003-151972A). That is, introducing HSi(OC₂H₅)₃ and (CH₂=CH)Si(OCH₃)₃ to perform a plasma process allowed an Si—O—C—H oxide film to be obtained.
[Patent document 1] JP-P2003-151972A

### SUMMARY OF THE INVENTION

By the way, it has been grasped that in the above-mentioned technique, a part is brought forth in which leak current exceeding 10⁻⁸ A/cm² occurs at the time of a voltage of 20 V.

Accordingly, the problem to be solved by the present invention is to provide an insulating film having a high quality, of which the dielectric constant is lower than that of the conventional SiO₂, and in which no leak current exceeding 10⁻⁸ A/cm² occurs at the time of a voltage of 20 V.

Making an aggressive investigation on the above-mentioned problems led to obtaining the revelation that the cause of the problems lay in the employed raw material (HSi(OC₂H₅)₃). That is, the reason why the revelation was obtained is that said problems were not observed in a case where HSi(OCH₃)₃ having no —OC₂H₅ was employed.

The present invention has been accomplished based upon the above-mention knowledge.

That is, in order to solve the above-mentioned problems, a method of forming a film is applied, said film forming method comprising: a [I] supply step of supplying one or more chemical compounds selected from the group belonging to the following [I]; a [II] supply step of supplying one or more chemical compounds selected from the group belonging to the following [II]; and a film forming step of decomposing chemical compounds supplied in said [I] supply step, and chemical compounds supplied in said [II] supply step, thereby to deposit them on a substrate.

The present invention provides a film obtained in said film forming method.

Moreover, the present invention provides a film forming material being a material for forming a film, said film forming material containing one or more chemical compounds selected from the group belonging to the following [I] and one or more chemical compounds selected from the group belonging to the following [II]:
HSi(OCH₃)₃, H₂Si(OCH₃)₂, and HSi(CH₃) (OCH₃)₂ [I]
(CH₂=CH)Si(OCH₃)₃, (CH₂═CH)Si(OC₂H₅)₃, (CH₂=CH)Si(CH₃)(OCH₃)₂, (CH₂=CH)Si(CH₃) (OC₂H₅)₂, (CH₂=CH)Si(CH₃)₂(OCH₃), and (CH₂=CH)Si(CH₃)₂ (OC₂H₅) [II]

In the present invention mentioned above, the chemical compounds belonging to the said [II] are, particularly, chemical compounds belonging to the following [IIa]:
(CH₂═CH)Si(OCH₃)₃, (CH₂═CH)Si(CH₃)(OCH₃)₂, and (CH₂═CH)Si(CH₃)₂ (OCH₃) [IIa]

The film for which the present invention aims is an insulating film containing Si, O, C, and H. Particularly, it is an interlayer insulating film of which the dielectric constant is 2.5 or less. Also, its film is formed on a substrate with a chemical vapor deposition process.

So as to form an insulating film (interlayer insulating film) having a dielectric constant of 2.5 or less and yet containing Si, O, C, and H as members, the present invention employs one or more chemical compounds selected from the group belonging to the above-mentioned [I] and one or more chemical compounds selected from the group belonging to the above-mentioned [II] (particularly, the above-mentioned [IIa]), whereby the above insulating film is excellent in the following characteristics as compared with the case where, for example, HSi(OC₂H₅)₃ and (CH₂═CH)Si(OCH₃)₃ are employed:

(1) The chemical compounds of the above-mentioned [I] of which a vapor pressure is higher than that of HSi(OC₂H₅)₃ enables a stable film forming.

(2) A composition ratio of Si, O, C, and H is more uniform.

(3) No leak current exceeding 10⁻⁸ A/cm² occurs at the time of a voltage of 20 V.

### BRIEF DESCRIPTION OF THE DRAWING

This and other objects, features and advantages of the present invention will become apparent upon a reading of the following detailed description and a drawing, in which:

FIG. 1 is a schematic diagram illustrating a chemical vapor deposition (CVD) apparatus.

### DESCRIPTION OF THE EMBODIMENTS

The insulating film (interlayer insulating film) forming material in accordance with the present invention is comprised of one or more chemical compounds selected from the group belonging to the above-mentioned [I] and one or more chemical compounds selected from the group belonging to the above-mentioned [II] (particularly, the above-mentioned [IIa]).

One or more chemical compounds selected from the group belonging to the above-mentioned [I] and one or more chemical compounds selected from the group belonging to the above-mentioned [II] (particularly, the above-mentioned [IIa]) are supplied simultaneously or separately. And, they are decomposed by at least one means selected from the means of plasma, light, a high-frequency wave, laser, and heat, and are deposited on a substrate. Doing so allows the film to be formed. In particular, the insulating film containing Si, O, C, and H is formed. In particular, the interlayer insulating film of which the dielectric constant is 2.5 or less is formed.

Specific embodiments will be described below.

### Embodiment 1

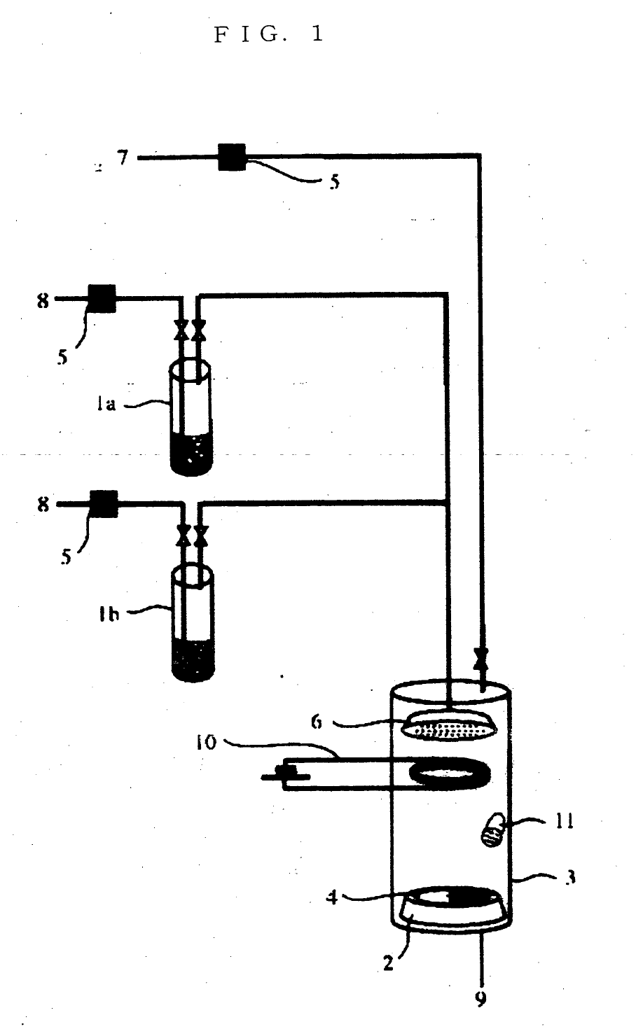

FIG. 1 is a schematic diagram illustrating a CVD apparatus embodying a chemical vapor deposition process according to the present invention.

Referring to FIG. 1, 1a and 1b represent raw material containers, 2 represents a plasma discharge electrode/heater, and 3 represents a reactor. 4 represents a substrate placed upon the plasma discharge electrode/heater 2. 5 represents a gas flow controller, and 6 represents a plasma discharge electrode/gas outlet shower head. 7 represents a reaction gas inlet, and 8 represents a carrier gas inlet. 9 represents an exhaust pipe, 10 represents a hot filament, and 11 represents a photo-irradiation device.

A film was formed on the Si substrate 4 using the CVD apparatus shown in FIG. 1.

That is, HSi(OCH₃)₃ was placed in the container 1a, and (CH₂=CH)Si(OCH₃)₃ was placed in the container 1b. The inside of the containers 1a and 1b were maintained at 0-100° C. And, carrier gas was supplied at a ratio of 20 ml/min into each of the containers 1a and 1b. Also, simultaneously with it, oxygen diluted to 5% or less with nitrogen was supplied as reaction gas at a rate of 60 ml/min or less.

The vaporized HSi(OCH₃)₃ and (CH₂=CH)Si(OCH₃)₃ were introduced into the reactor 3 via a conduit together with the oxygen and the carrier gas. At this time, the system was evacuated at 500 torr or less. The Si substrate 4 was heated to 250-450° C. with the plasma discharge electrode/heater 2. The plasma discharge was induced within the reactor 3.

The film was formed on the Si substrate 4 in such a manner.

This film was analyzed with an XPS (X-ray photoelectron spectroscopy). As a result, it was found out that the film contained Si, O, and C. In addition, it is impossible to detect H with the XPS. Also, the film was checked with an FT-IR (Fourier Transform Infrared Radiometer). As a result, oscillation peaks coming from an Si—O linkage and a CH₂—CH₂ linkage were observed. Thus, it was found out that the film contained Si, O, C, and H as members.

A current-voltage characteristic was measured with electrodes made of aluminum evaporated on ten locations of this film. This result demonstrated that the leak current at 20 V was 10⁻⁸ A/cm² or less at all locations. Thus, it was excellent as an insulating film.

Further, a dielectric strength-voltage characteristic of the film was checked. And, calculating the dielectric constant from the film thickness and the electrode showed that it was 2.5 or less.

### Embodiment 2

The embodiment 2 was carried out similarly to the embodiment 1 with the exception that H₂Si(OCH₃)₂ was employed instead of HSi(OCH₃)₃.

This formed film was one similar to the film formed in the embodiment 1.

### Embodiment 3

The embodiment 3 was carried out similarly to the embodiment 1 with the exception that HSi(CH₃)(OCH₃)₂ was employed instead of HSi(OCH₃)₃.

This formed film was one similar to the film formed in the embodiment 1.

### Embodiment 4

The embodiment 4 was carried out similarly to the embodiment 1 with the exception that (CH₂=CH)Si(CH₃) (OCH₃)₂ was employed instead of (CH₂=CH)Si(OCH₃)₃.

This formed film was one similar to the film formed in the embodiment 1.

### Embodiment 5

The embodiment 5 was carried out similarly to the embodiment 1 with the exception that (CH₂=CH)Si(CH₃)₂(OCH₃) was employed instead of (CH₂=CH)Si(OCH₃)₃.

This formed film was one similar to the film formed in the embodiment 1.

### Embodiment 6

The embodiment 6 was carried out similarly to the embodiment 1 with the exception that (CH₂=CH)Si(OC₂H₅)₃ was employed instead of (CH₂=CH)Si(OCH₃)₃.

This formed film was a film almost similar to the film formed in the embodiment 1. However, it was inferior in in-plane uniformity of the composition of the film as compared with a case of the embodiment 1.

### Embodiment 7

The embodiment 7 was carried out similarly to the embodiment 6 with the exception that (CH₂=CH)Si(CH₃) (OC₂H₅)₂ was employed instead of (CH₂=CH) Si (OC₂H₅) 3.

This formed film was one similar to the film formed in the embodiment 6.

### Embodiment 8

The embodiment 8 was carried out similarly to the embodiment 6 with the exception that (CH₂=CH)Si(CH₃)₂(OC₂H₅) was employed instead of (CH₂=CH)Si(OC₂H₅)₃.

This formed film was one similar to the film formed in the embodiment 6.

### Embodiment 9

The embodiment 9 was carried out similarly to the embodiment 1 with the exception that photo-irradiation was carried out instead of the plasma discharge.

This formed film was one similar to the film formed in the embodiment 1.

### COMPARATIVE EXAMPLE 1

The comparative example 1 was carried out similarly to the embodiment 1 with the exception that HSi(OC₂H₅)₃ was employed instead of HSi(OCH₃)₃.

This formed film was inferior to the films formed in the embodiments 1 and 6.

That is, its uniformity of the composition ratio of Si, O, C, and H was inferior to that of the films obtained in the embodiments 1 and 6 in the in-plane direction of the substrate.

Also, the leak current at 20 V exceeded 10⁻⁸ A/cm² at four locations of ten.

Particularly, the present invention can be usefully applied in the semiconductor fields.

What is claimed is:

1. A method of forming a film, comprising:
a [I] supply step of supplying one or more chemical compounds selected from the group belonging to the following [I];
a [II] supply step of supplying one or more chemical compounds selected from the group belonging to the following [II]; and
a film forming step of decomposing chemical compounds supplied in said [I] supply step, and chemical compounds supplied in said [II] supply step, thereby to deposit them on a substrate:
HSi(OCH₃)₃, H₂Si(OCH₃)₂, and HSi(CH₃) (OCH₃)₂ [I]
(CH₂=CH)Si(OCH₃)₃, (CH₂=CH)Si(OC₂H₅)₃, (CH₂=CH)Si(CH₃)(OCH₃)₂, (CH₂=CH)Si(CH₃) (OC₂H₅)₂, (CH₂=CH)Si(CH₃)₂(OCH₃), and (CH₂=CH)Si(CH₃)₂ (OC₂H₅) [II]

2. The film forming method as claimed in claim 1, wherein the chemical compounds belonging to said [II] are chemical compounds belonging to the following [IIa]:
(CH₂=CH)Si(OCH₃)₃, (CH₂=CH)Si(CH₃)(OCH₃)₂, and (CH₂=CH)Si(CH₃)₂(OCH₃) [IIa]

3. The film forming method as claimed in claim 1, wherein the chemical compounds belonging to said [II] is (CH₂=CH)Si(OCH₃)₃.

4. The film forming method as claimed in claim 1, wherein the chemical compounds belonging to said [II] is (CH₂=CH)Si(CH₃) (OCH₃)₂.

5. The film forming method as claimed in claim 1, wherein the chemical compounds belonging to said [II] is (CH₂=CH)Si(CH₃)₂(OCH₃).

6. The film forming method as claimed in claim 1, wherein said film is an insulating film containing Si, O, C, and H.

7. The film forming method as claimed in claim 1, wherein said film is an interlayer insulating film of which a dielectric constant is 2.5 or less.

8. The film forming method as claimed in claim 1, wherein the film is formed on a substrate with a CVD process.
